(19) United States
(12) Patent Application Publication
(10) Pub. No.: US 2009/0025962 A1
(43) Pub. Date: Jan. 29, 2009

(54) Electronic Module Expansion Bridge

(76) Inventor: John A. Gelardi, Wake Forest, NC (US)

Correspondence Address: MEADWESTVACO CORPORATION;ATTN: IP LEGAL (DOCKET ADMINISTRATOR), 1021 MAIN CAMPUS DRIVE, CENTENNIAL CAMPUS, RALEIGH, NC, 27606, US

(21) Appl. No.: 12/088,546

(22) PCT Filed: Sep. 29, 2006
(86) PCT No.: PCT/US2006/038558

§ 371 Date: Jul. 29, 2008

Related U.S. Application Data
(60) Provisional application No. 60/722,725, filed on Sep. 30, 2005.

(51) Int. Cl. H05K 1/00; H05K 3/00

(52) U.S. Cl. 174/254; 29/842

(57) ABSTRACT

Taught herein is an electronic module expansion bridge (115). In an exemplary embodiment, the bridge (115) includes a flexible mounting plate (155). In contact with the mounting plate (155) is a conductive lead (160) with at least one first contact area (165) and at least one second contact area (170). The bridge (115) is configured to connect an electronic module (110), at the first contact area (165), to a conductive trace (125) that is in contact with a substrate (105) at the second contact area (170). In one embodiment, a substrate (105) is used to form a package (100) for enclosing one or more articles. An electronic module (110) is positioned in the package (100) and connected to the conductive trace (125) via the bridge (115). In an alternative embodiment, the bridge (115) is extended to form an inner sleeve to enclose or otherwise cover or protect the electronic module (110).

### RELATED APPLICATIONS

This application claims priority to U.S. Application No. 60/722,725, filed Sep. 30, 2005, the entirety of which is incorporated herein by reference.

### TECHNICAL FIELD

The present invention relates generally to packages and, more specifically, to packages that include printed circuitry for use with one or more electronic modules.

### BACKGROUND OF THE INVENTION

Packaging that includes printed circuitry for use with one or more electronic modules, or so-called “smart packaging,” are configured to provide various interactive experiences for a user. Common examples include sound output and/or light output when a user touches a portion of the package. In addition to clever graphics and marketing schemes, the interactive element(s) of smart packages can entice a potential consumer to purchase a product.

Smart packages are, however, not without fault. Typically, smart packages comprise a plurality of materials with varying coefficients of thermal expansion. In response to ambient conditions, the various materials typically expand or contract at different rates, thus opening the circuit created by the printed circuitry and the electronic module(s).

Further, assembly problems exist with regard to aligning and connecting the typically small contacts on the printed circuit board (PCB) of the electronic module to the conductive traces of the package. In addition, the known solutions severely limit the placement of the electronic modules with respect to the package traces.

Accordingly, there remains in the art a need for a device to connect the electrical contacts of one or more electronic modules and the conductive traces of a smart package to eliminate the effects of thermal expansion and contraction, and to increase the viable manufacturing and configuration options for these components.

### SUMMARY OF THE INVENTION

The various embodiments of the present invention overcome the present shortcomings of the prior art by providing a bridge to connect the contacts of at least one electronic module to the circuitry of a substrate. The bridge includes a mounting plate and at least one conductive trace in contact with the mounting plate. In some embodiments, the mounting plate is manufactured from a flexible, non-conductive material. In further embodiments, the mounting plate is configured with at least one notch.

The conductive trace includes at least one first contact area configured to be in contact with a first circuit, for example, the electronic module. The conductive trace further includes at least one second contact area configured to be in contact with a second circuit, for example, the circuitry. In the illustrated embodiments the second contact area is wider than the first contact area, but in alternative embodiments the first and second contact areas are substantially smaller in size.

An electronic package is also provided herein. The electronic package includes a substrate and an electronic module connected via a bridge. The substrate includes a conductive trace and the electronic module includes at least one output element. The bridge includes a mounting plate with at least one conductive trace in contact with the mounting plate. The conductive trace includes at least one first contact area configured to be in contact with the electronic module and at least one second contact area configured to be in contact with the circuitry.

### BRIEF DESCRIPTION OF THE DRAWINGS

FIG. 1 is a perspective view of an exemplary embodiment of a package, according to the present invention.

FIG. 2 is a perspective view of an exemplary embodiment of a foldable bridge, according to the present invention.

FIG. 3 is a perspective view of an alternative embodiment of a foldable bridge including a plurality of notches, according to the present invention.

FIG. 4 is a perspective view of another alternative embodiment of a foldable bridge, according to the present invention

FIG. 5 is a perspective view of yet another alternative embodiment of a foldable bridge, according to the present invention.

### DETAILED DESCRIPTION OF THE INVENTION

As required, detailed embodiments of the present invention are disclosed herein. It must be understood that the disclosed embodiments are merely exemplary of the invention that may be embodied in various and alternative forms, and combinations thereof. As used herein, the word “exemplary” is used expansively to refer to embodiments that serve as an illustration, specimen, model or pattern. The figures are not necessarily to scale and some features may be exaggerated or minimized to show details of particular components. In other instances, well-known components, systems, materials or methods have not been described in detail in order to avoid obscuring the present invention. Therefore, specific structural and functional details disclosed herein are not to be interpreted as limiting, but merely as a basis for the claims and as a representative basis for teaching one skilled in the art to variously employ the present invention.

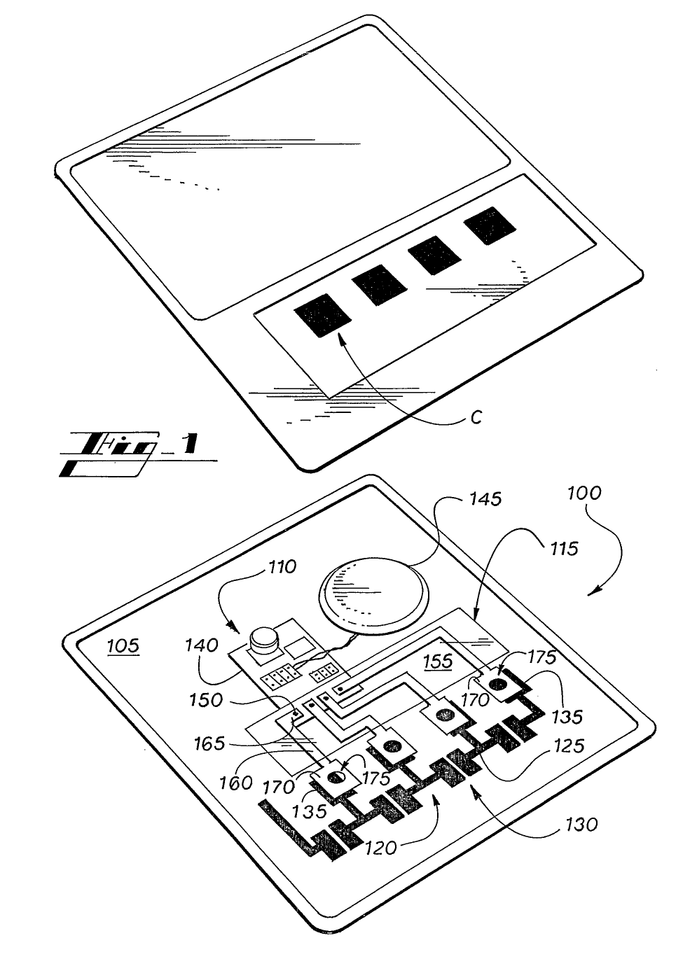

Referring now to the drawings wherein like numerals represent like elements throughout the several views, FIG. 1 illustrates a perspective view of an exemplary package 100, according to the present invention. The illustrated package 100 is formed from a substrate 105 and includes an electronic module 110 that is connected to printed circuitry 120 via a bridge 115. The dimensions of the package 100 and any graphic designs printed thereon are merely design choices and may be dependent upon the article type contained within the package 100.

Typically, the substrate 105 is constructed of non-conductive material such as, but not limited to, paper, paperboard, cardboard, plastic, epoxy or any combination thereof. Alternatively, conductive substrates with insulative layers positioned between the conductive substrate and circuitry 120 are contemplated.

The illustrated circuitry 120 includes conductive traces 125, a portion of which forms at least one touch area 130 that is configured to complete a circuit if, for example, a user holds the package 100 at the touch area 130. By further example, a conductive element C can be used to connect the conductive traces 125 of a touch area 130 to complete the circuit. Another portion of the conductive traces 125 form at least one trace contact area 135 that is configured to connect the circuitry 120 to the bridge 115.

The illustrated printed circuitry 120 is applied directly on the substrate 106, in a manner well known by those skilled in the art. Here, the circuitry 120 is printed on the substrate 105 using conventional printing or lithography methods such as, but not limited to ink jet, silk screen, or off-set methods. The inks used in the printing method to form the circuitry 120 are conductive inks selected based upon the performance needs of the individual circuits and the substrate type. Conductive inks typically include metals such as, but not limited to, copper or silver. Some non-metallic elements such as carbon can also be used. Here, the ink used to form the illustrated circuitry 120 is a carbon-based conductive ink readily understood by those skilled in the art.

The configuration of the circuitry 120 is a design choice which, in the exemplary embodiment, is based at least in part on the position of the electronic module 110 and the touch areas 130. Further, the number of conductive traces 125, touch areas 130, and trace contact areas 135 are a design choice which, in the exemplary embodiment, are based at least in part on the composition of the electronic module 110, as described below in detail.

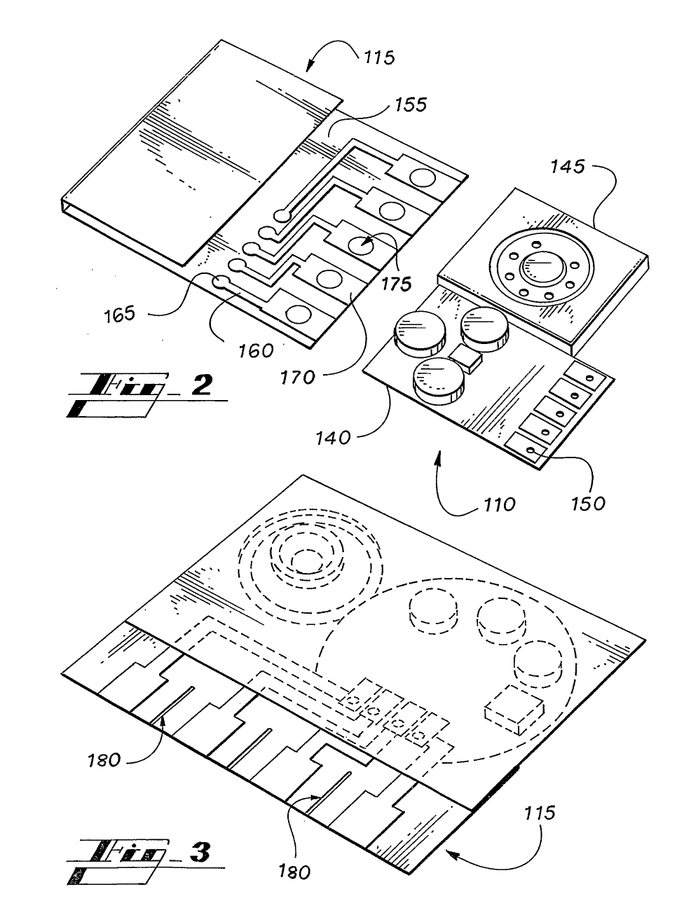

The electronic module 110 includes a printed circuit board (PCB) 140. The PCB 140 can include power supply elements and various electronic elements required to operate one or more output elements 145. The output elements 145 can include, but are not limited to, an audio output device, a light output device, a cooling element, a heating element, a fan element, a picture element, a video element, or various other elements that appeal to the vision sense, audition sense, gustation sense, or olfaction sense, or any combination thereof. While the sensory perception of a human being is considered in the exemplary embodiments, interaction between a package and programmable machine including artificial intelligence is contemplated. The output elements 145 can be located on the PCB 140 or can be connected to the PCB 140 via, for example, a conductive trace disposed within or on the substrate 105, a conductive trace disposed within or on a bridge, or a traditional jumper wire. The illustrated PCB 140 further includes at least one contact lead 150 (best shown in FIG. 2), such as a plated through-hole. The contact lead 150 provides an output from the PCB 140 to connect the circuitry 120 to the electronic module 110 via the bridge 115.

The bridge 115 includes a mounting plate 155. The illustrated mounting plate 155 is constructed of non-conductive material such as, but not limited to, paper, paperboard, cardboard, plastic, epoxy, or any combination thereof. In the illustrated embodiment, the mounting plate 155 is advantageously constructed of a substantially transparent and flexible plastic to aid in positioning the bridge 115 during assembly. The illustrated mounting plate 155 includes an arrangement of conductive leads 160 that are formed via a method as described above for the circuitry 120. Each conductive lead 160 connects a first contact area 165 to a second contact area 170. It is contemplated that, in some embodiments, the mounting plate 155 is composed of a conductive substrate with insulative layers positioned between the conductive substrate and the conductive leads 160, the first contact area 165, and the second contact area 170.

In the illustrated embodiment, the first contact area 165 is positioned in a face-contacting relationship with the contact lead 150 and secured with a rivet. Other means for connection include, but is not limited to, friction fit or simply overlaying in a face-contacting orientation; mechanical fasteners such as screws, nuts, washers, bolts, nails; processes such as soldering or welding; or chemical bonding with a variety of adhesives, tapes; and combinations thereof, and the like.

Each first contact area 165 is dimensioned and configured to align and connect with a respective contact lead 150. Each second contact area 170 is dimensioned and configured to align and connect with a respective trace contact area 135 via any means for connection. In the illustrated embodiment, each second contact area 170 includes an aperture 175. The aperture 175 is configured to aid in attaching the bridge 115 to the substrate 105.

In the illustrated embodiment, the contact leads 150 are small and tightly spaced relative to the trace contact areas 135, which are larger and more widely spaced. Further, the electronic module 100 is small relative to the expansive substrate 105. Future implementations will likely yield still smaller electronic modules. Due to this, it is desirable to have a bridge 115 to connect the small contact leads 150 to larger, more widely spaced trace contact areas 135. These contact areas 135 provide a greater area of contact and maintain a better connection when there is movement between the contact areas, such as may occur with materials of varying expansion coefficients. The wide spaced trace contact areas 135 also provide for the touch areas 130 to span, for example, a significant area of the substrate 105 so as to provide an adequate touch surface for a user.

In alternative embodiments, the bridge 115 is extended and is foldable to enclose or otherwise cover, protect, and position the electronic module 110. As shown in FIG. 2, for example, the mounting plate 155 is extended and folded to create an enclosure to house the electronic module 110. Further, the mounting plate 155 can include one or more notches 180 as shown in FIG. 3. The notches 180 provide increased flexibility with regard to the number of viable mounting options for the electronic module 110. In addition, the notches 180 limit the effects of expansion and contraction of materials with dissimilar expansion coefficients.

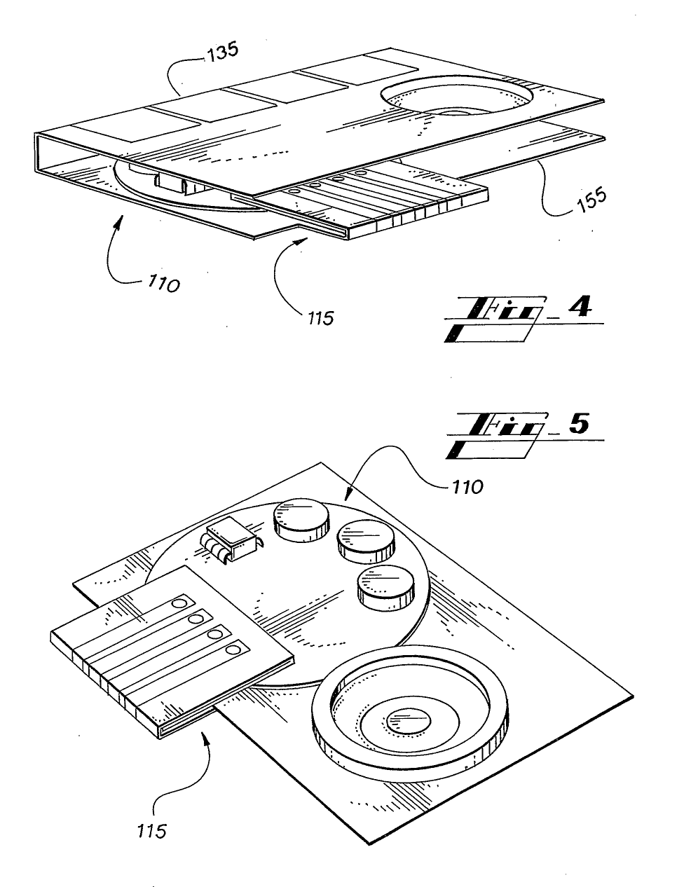

Another alternative embodiment for the bridge 115 is provided with reference to FIG. 4. As shown, the mounting plate 155 is foldable to form an inner sleeve around the electronic module 110 and to facilitate connection of the electronic module 110 to trace contact areas above the electronic module 110. Accordingly, this bridge 115 and electronic module 110, inclusive, may be inserted into an outer sleeve (not shown) to assemble a package. The outer sleeve, formed from a substrate described herein, includes printed circuitry where trace contact areas are positioned on the inside of the outer sleeve to align with and contact a respective contact area 135 on the bridge 115. Similarly, FIG. 5 shows an alternative embodiment of a bridge 115 that is foldable to facilitate the connection of the electronic module 110 to trace contact areas 135 (not shown) positioned below the module.

An exemplary assembly of the package 100 will now be described. The bridge 115 is first secured to the electronic module 110. More specifically, the contact leads 150 are connected to the mounting plate 155 with rivets such that each first contact area 165 is at least partially in contact with a respective contact lead 150, as best shown in FIG. 1. Other means for connection are contemplated.

The electronic module 110 is positioned on the substrate 105 such that the second contact areas 170 align with a respective trace contact area 135. Further, the electronic module 110 is secured to the substrate 105 by any means for connection. In the exemplary embodiment, the bridge 115 is connected to the substrate 105 with tape (not shown) such that the tape overlaps both the bridge 115 and the substrate 105 and, more specifically, such that the tape at least partially overlaps each trace contact area 135 through each aperture 175.

In an alternative embodiment, each second contact area 170 may be placed in a face-contacting relationship with a trace contact area 135 by providing a bend or series of bends in the mounting plate 155, which acts as a spring to hold the mounting plate 155 against the substrate 105. This can be further realized by the addition of notches 180.

In additional alternative embodiments, each second contact area 170 is secured to a respective trace contact area 135 by means for connecting that includes conductive tape or conductive adhesive positioned between the second contact area 170 and trace contact area 135 to secure the bridge 115 to the substrate 105. Here, the respective traces are placed in a face-contacting relationship and separated by the conductive tape or adhesive (not shown).

The law does not require and it is economically prohibitive to illustrate and teach every possible embodiment of the present claims. Hence, the above-described embodiments are merely exemplary illustrations of implementations set forth for a clear understanding of the principles of the invention. Variations, modifications, and combinations may be made to the above-described embodiments without departing from the scope of the claims. All such variations, modifications, and combinations are included herein by the scope of this disclosure and the following claims.

What is claimed is:

1. A circuit bridge 115, comprising:
a mounting plate 155; and
at least one conductive lead 160 in contact with said plate 155, wherein said lead 160 comprises at least one first contact area 165 configured to be in contact with a first circuit and at least one distal second contact area 170 configured to be in contact with a second circuit.

2. The circuit bridge 115 of claim 1, wherein said plate 155 is flexible such that said plate 155 is capable of being positioned so as to accommodate a plurality of positions of said first circuit and said second circuit.

3. The circuit bridge 115 of claim 2, wherein said plate 155 is configured with at least one notch 180, said notch 180 providing further accommodation for a plurality of positions of said first circuit and said second circuit.

4. The circuit bridge 115 of claim 1, wherein said plate 155 is configured to comprise at least one of said first circuit and said second circuit.

5. The circuit bridge 115 of claim 1, wherein said first circuit is an electronic module 110 comprising at least one output element 145.

6. The circuit bridge 115 of claim 1, wherein said second circuit is a conductive trace 125 in contact with a substrate 105.

7. The circuit bridge 115 of claim 1, wherein said first contact area 165 differs in size from said second contact area 170.

8. The circuit bridge of claim 1, wherein said first contact area 165 and said second contact area 170 are substantially the same size.

9. An electronic package 100, comprising:
a substrate 105, said substrate 105 comprising a conductive trace 125;
an electronic module 110, said electronic module 110 comprising at least one output element 145; and
a bridge 115 comprising:
a mounting plate 155;
at least one conductive lead 160 in contact with said mounting plate 155, said conductive lead 160 comprising a first contact area 165 and a second distal contact area 170;
wherein said bridge 115 is configured to connect said electronic module 110 at said first contact area 165 to said conductive trace 125 at said second contact area 170.

10. The electronic package 100 of claim 9 further comprising an exterior structure, said exterior structure comprising a third contact area that is in contact with one of said first contact area 165 and said second contact area 170.

11. A method of manufacturing an electronic package 100, comprising:
providing an exterior structure 105 comprising a conductive trace 125 with a trace contact area 135;
providing an electronic module 110 comprising a contact lead 150;
providing a bridge 115 comprising:
a mounting plate 155;
at least one conductive lead 160, a first contact area 165, and a second contact area 175;
cooperatively attaching the electronic module 110 to the exterior structure 105;
mounting the bridge 115 to span between the contact lead 150 and the conductive trace 125;
connecting the first contact area 165 to the contact lead 150; and
connecting the second contact area 175 to the conductive trace 125.

12. The method of claim 11, further comprising the step of providing an output element 145 cooperatively attached to the structure 105 or the electronic module 110.

13. The method of claim 11, wherein the step of providing a bridge 115 further includes a first contact area 165 which is smaller than the second contact area 175.
